(19) United States
(12) Patent Application Publication
(10) Pub. No.: US 2026/0327804 A1
(43) Pub. Date: Oct. 22, 2026

(54) DEPOSITION EQUIPMENT FOR REDUCING BACK-SIDE DEPOSITION

(71) Applicant: Skytech Inc., Hsinchu County (TW)

(72) Inventors: TA-HAO KUO, Hsinchu County (TW); CHUN-FU WANG, Hsinchu County (TW); YU-CHI LIU, Hsinchu County (TW)

(21) Appl. No.: 19/190,142

(22) Filed: Apr. 25, 2025

(30) Foreign Application Priority Data
Apr. 21, 2025 (TW) 114115051

(51) Int. Cl. C23C 16/455; C23C 16/458

(52) U.S. Cl. CPC C23C 16/45591; C23C 16/4583

(57) ABSTRACT

This disclosure is a deposition equipment for reducing back-side deposition, which comprises a carrier plate, a flow diversion unit, and a base. The carrier plate carries at least one wafer, and the flow diversion unit is disposed within a receiving groove of the carrier plate. A first flow diversion channel and a second flow diversion channel are formed between the flow diversion unit and the receiving groove. A communication space is formed between the base and the carrier plate. An air inlet line is connected to the communication space and transports gas to the communication space, wherein the gas is transported through the communication space to the first and the second flow diversion channels, such that the gas forms a gas curtain on the back-side and around the wafer to prevent film formation on the back-side of the wafer.

### CROSS-REFERENCE TO RELATED APPLICATIONS

This non-provisional application claims priority claim under 35 U.S.C. § 119(a) on Taiwan Patent Application No. 114115051 filed Apr. 21, 2025, the entire contents of which are incorporated herein by reference.

### TECHNICAL FIELD

This invention relates to a deposition equipment for reducing back-side deposition, thereby preventing the formation of deposited films on the back-side of a wafer during the deposition process.

### BACKGROUND

Chemical Vapor Deposition (CVD), Physical Vapor Deposition (PVD), and Atomic Layer Deposition (ALD) represent prevalent thin film deposition equipment and are extensively employed in manufacturing processes for integrated circuits, light-emitting diodes, displays, and the like.

A deposition equipment mainly includes a deposition chamber and a wafer carrier plate, wherein the wafer carrier plate is located inside the deposition chamber and is used to carry at least one wafer. Considering chemical vapor deposition (CVD) and atomic layer deposition (ALD) as illustrative examples, CVD entails the introduction of a reactive gas, containing the constituent elements of the desired material, into the deposition chamber. Under specific temperature or energy conditions, these gaseous molecules undergo a chemical reaction at the wafer surface, resulting in the formation of a thin film thereon.

Atomic Layer Deposition (ALD), on the other hand, involves inputting one type of precursor gas into the deposition chamber at a time, allowing the precursor gas to react with the surface of the wafer. Subsequently, an inert gas is transported into the deposition chamber to thoroughly purge unreacted precursors and byproducts from within the deposition chamber. Then, another type of precursor gas is introduced to react with the substance formed on the wafer surface in the previous step, forming the deposition of a single atomic layer. This cycle is repeated multiple times until the desired thin film thickness is achieved.

Thin film deposition primarily takes place on the front (upper) surface of the wafer during the deposition process. Nevertheless, wafers generally exhibit a degree of non-planarity. Upon placement of the wafer onto the carrier plate, the peripheral region of the wafer may exhibit an upward curvature or protrusion. Notably, during chemical vapor deposition (CVD) or atomic layer deposition (ALD), the back-side of the wafer is also exposed to the reactive gas or precursor gas, leading to film formation on the back-side, particularly pronounced in the back-side edge region.

The deposited film on the back-side of the wafer can negatively impact the manufacturing yield and reliability of semiconductor devices. Specifically, back-side film can impede chip heat dissipation and may lead to short circuits or leakage paths on the back-side of chip. Furthermore, back-side film can be disadvantageous for subsequent bonding or other packaging procedures and may induce wafer warpage, thereby compromising the mechanical integrity of the wafer. Consequently, following the completion of the wafer deposition process, an additional back-side grinding and polishing step is typically required to eliminate the deposited film.

### SUMMARY

As elucidated in the prior art, the deposition process frequently results in the formation of a film on the back-side of the wafer, consequently impacting the yield and reliability of downstream chip fabrication. Accordingly, a post-deposition back-side polishing and grinding step is necessitated, adding to the overall process cost. To overcome this limitation, this invention introduces a deposition equipment for reducing back-side deposition, thereby preventing film formation on the back-side of the wafer during the deposition process. This not only enhances product yield and reliability but also eliminates the process steps of grinding and polishing the back-side of the wafer, which is beneficial for reducing the cost of the process.

An object of this invention is to provide a deposition equipment for reducing back-side deposition, mainly comprising at least one receiving groove disposed on a carrier plate, and a flow diversion unit disposed within the receiving groove. A first flow diversion channel is formed between the outer side surface of the flow diversion unit and the receiving groove, and a second flow diversion channel is formed between the inner side surface of the flow diversion unit and the receiving groove, wherein the first flow diversion channel is located on the outer side of the second flow diversion channel.

The wafer, when positioned on the carrier plate, will overlay the inner second flow diversion channel, directing the gas emanating from the inner second flow diversion channel towards the back-side of the wafer. This gas then traverses along the back-side of the wafer and the carrying surface of the carrier plate towards the periphery, effectively impeding the flow or diffusion of reactive or precursor gases towards the back-side of the wafer, thus preventing back-side film deposition. Furthermore, the gas discharged from the outer first flow diversion channel generates a gas curtain around the outer side of the wafer, providing an additional barrier against the flow or diffusion of reactive or precursor gases towards both the outer edges and the back-side of the wafer, further ensuring the prevention of back-side film formation.

To achieve the foregoing objectives, this disclosure provides a deposition equipment for reducing back-side deposition, which comprises a carrier plate, at least one flow diversion, a base and a gas inlet line. The carrier plate includes a carrying surface and at least one receiving groove, wherein the carrying surface is used to carry a wafer, and the receiving groove is located on the carrying surface. The flow diversion unit is disposed within the receiving groove of the carrier plate, wherein the wafer located on the carrier plate overlaps with a portion of the receiving groove and a portion of the flow diversion unit. The flow diversion unit comprises an outer side surface and an inner side surface. A first flow diversion channel is formed between the outer side surface of the flow diversion unit and the receiving groove, and a second flow diversion channel is formed between the inner side surface of the flow diversion unit and the receiving groove. The first flow diversion channel is located on the outer side of the second flow diversion channel. The base is located below the carrier plate and used to support the carrier plate, wherein a communication space is formed between the base and the carrier plate, and the communication space connects the first flow diversion channel and the second flow diversion channel. The gas inlet line is connected to the communication space and used to transport a gas through the communication space to the first flow diversion channel and the second flow diversion channel.

This invention proposes a deposition equipment for reducing back-side deposition, which can avoid film formation on the back-side of the wafer during the deposition process. Furthermore, after completing the deposition step, it will not be necessary to grind and polish the back-side of the wafer, which is beneficial for reducing process steps and costs.

### BRIEF DESCRIPTION OF THE DRAWINGS

FIG. 1 is a cross-sectional view of a deposition equipment for reducing back-side deposition according to an embodiment of the invention.

FIG. 2 is a schematic exploded view of the deposition equipment for reducing back-side deposition according to an embodiment of the invention.

FIG. 3 is a partial cross-sectional exploded view of the deposition equipment for reducing back-side deposition according to an embodiment of the invention.

FIG. 4 is a partial cross-sectional exploded view of the deposition equipment for reducing back-side deposition according to another embodiment of the invention.

FIG. 5 is a partial cross-sectional exploded view of the deposition equipment for reducing back-side deposition according to another embodiment of the invention.

FIG. 6 is a partial cross-sectional exploded view of the deposition equipment for reducing back-side deposition according to another embodiment of the invention.

FIG. 7 is a top view of the deposition equipment for reducing back-side deposition according to another embodiment of the invention.

FIG. 8 is a top view of the deposition equipment for reducing back-side deposition according to another embodiment of the invention.

### DETAILED DESCRIPTION

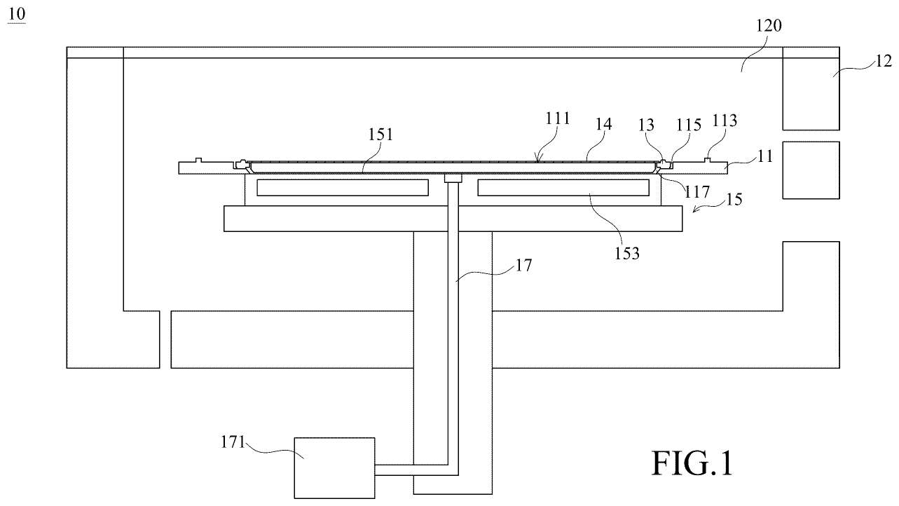

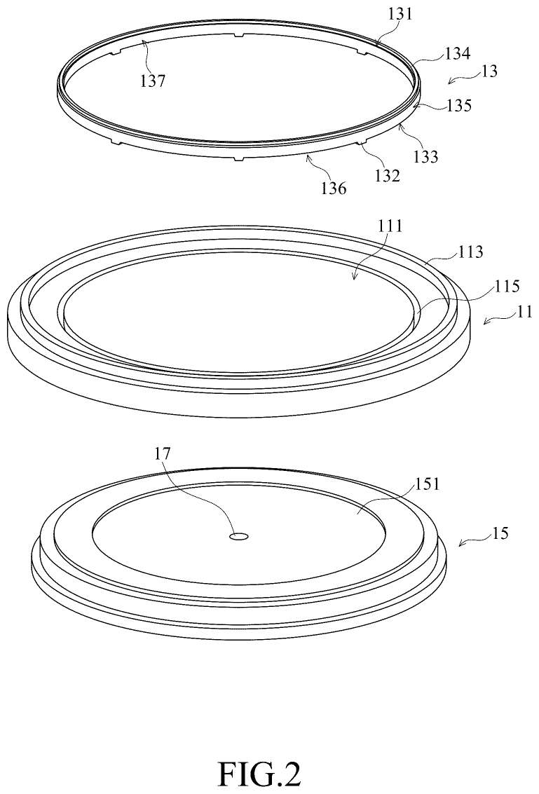

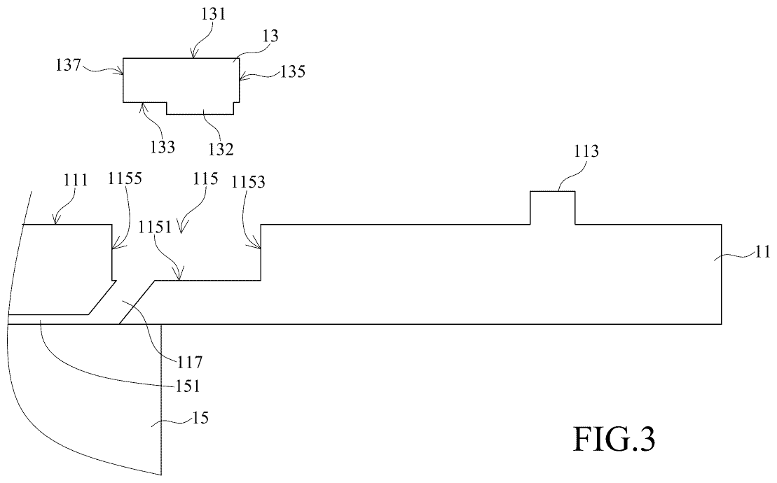

FIG. 1 is a cross-sectional view of a deposition equipment for reducing back-side deposition according to an embodiment of the invention. FIG. 2 is a schematic exploded view of the deposition equipment for reducing back-side deposition according to an embodiment of the invention. FIG. 3 is a partial cross-sectional exploded view of the deposition equipment for reducing back-side deposition according to an embodiment of the invention. The deposition equipment 10 for reducing back-side deposition mainly includes a carrier plate 11, at least one flow diversion unit 13, and at least one base 15. The base 15 is used to support the carrier plate 11, and the flow diversion unit 13 is disposed on the carrier plate 11. In one embodiment of the invention, the deposition equipment 10 may be a physical vapor deposition equipment, a chemical vapor deposition equipment, or an atomic layer deposition equipment. The deposition equipment 10 may include a chamber 12, and the carrier plate 11, the flow diversion unit 13, and the base 15 are located within a reaction space 120 of the chamber 12.

The carrier plate 11 may be disk-shaped, wherein the carrier plate 11 includes a carrying surface 111 for carrying the wafer 14. In one embodiment of this invention, the carrier plate 11 may include an annular protrusion 113, wherein the wafer 14 is placed on the carrying surface 111 located radially inward of the annular protrusion 113.

At least one receiving groove 115 can be disposed on the carrying surface 111 of the carrier plate 11, wherein the receiving groove 115 is located on the inner side of the annular protrusion 113, and the flow diversion unit 13 is disposed within the receiving groove 115 of the carrier plate 11. When the wafer 14 is placed on the carrying surface 111 of the carrier plate 11, the wafer 14 will overlap with a portion of the receiving groove 115 and a portion of the flow diversion unit 13.

The base 15 is located below the carrier plate 11 and is used to support the carrier plate 11. In one embodiment of the invention, when the base 15 is connected to the carrier plate 11, a communication space 151 is formed between the base 15 and the carrier plate 11. For example, a disk-shaped or cylindrical recess can be formed on the surface of the base 15 or the carrier plate 11. When the base 15 and the carrier plate 11 are connected, the communication space 151 will be formed between them.

The communication space 151 is in fluid communication with the receiving groove 115 of the carrier plate 11, such that the gas within the communication space 151 can be transported to the receiving groove 115 of the carrier plate 11. In another embodiment of this invention, the communication space 151 may be a pipeline disposed within the base 15 or the carrier plate 11.

In practical applications, the communication space 151 can be connected to a gas inlet line 17. For example, the gas inlet line 17 may be disposed within the base 15. The gas inlet line 17 is used to transport gas to the communication space 151 and then to the receiving groove 115 of the carrier plate 11 via the communication space 151. In one embodiment of the invention, the communication space 151 may be connected to the receiving groove 115 via a connecting channel 117, and the gas is transported to the receiving groove 115 via the connecting channel 117, wherein the connecting channel 117 may be a pipeline disposed within the carrier plate 11.

In one embodiment of the invention, as shown in FIG. 3, the receiving groove 115 of the carrier plate 11 may include a supporting surface 1151, a radially outer side surface 1153, and a radially inner side surface 1155. The supporting surface 1151 is located between the radially outer side surface 1153 and the radially inner side surface 1155. For example, the receiving groove 115 may be an annular groove disposed on the carrying surface 111 of the carrier plate 11.

The flow diversion unit 13 may include a top surface 131, a bottom surface 133, an outer side surface 135, and an inner side surface 137, and at least one protruding support portion 132 is disposed on the bottom surface 133 of the flow diversion unit 13. For example, the flow diversion unit 13 may be an annular structure, wherein a plurality of protruding support portions 132 can be spaced apart on the bottom surface 133 of the flow diversion unit 13, defining a spacing gap 136 between adjacent protruding support portions 132, as shown in FIG. 2.

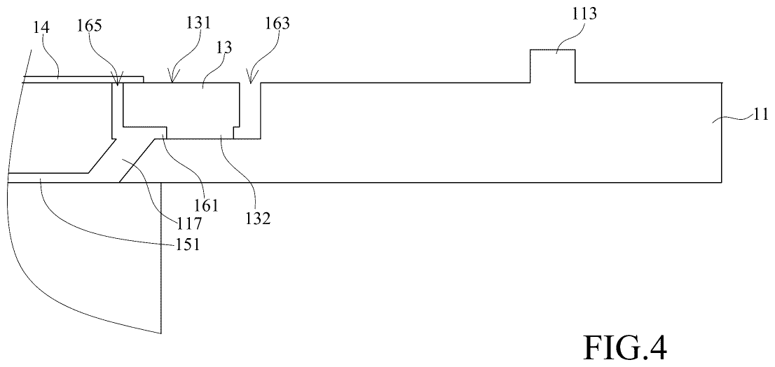

As shown in FIG. 4, the flow diversion unit 13 is placed within the receiving groove 115 of the carrier plate 11, wherein the protruding support portions 132 disposed on the bottom surface 133 of the flow diversion unit 13 will contact the supporting surface 1151 of the receiving groove 115. The protruding support portions 132 are used to support the weight of the flow diversion unit 13, wherein at least one diversion channel 161 is formed between the spacing gap 136 below the bottom surface 133 of the flow diversion unit 13 and the supporting surface 1151 of the receiving groove 115.

In addition, at least one first flow diversion channel 163 is formed between the outer side surface 135 of the flow diversion unit 13 and the radially outer side surface 1153 of the receiving groove 115, and at least one second flow diversion channel 165 is formed between the inner side surface 137 of the flow diversion unit 13 and the radially inner side surface 1155 of the receiving groove 115. The first flow diversion channel 163 is located on the outer side of the second flow diversion channel 165, and the diversion channel 161 is in communication with the first flow diversion channel 163 and the second flow diversion channel 165. In one embodiment of the invention, the cross-sectional area of the outer first flow diversion channel 163 may be larger than the cross-sectional area of the inner second flow diversion channel 165. For example, the cross-sectional area of the first flow diversion channel 163 may be between three and nine times that of the second flow diversion channel 165.

The communication space 151 between the base 15 and the carrier plate 11 connects the first flow diversion channel 163 and the second flow diversion channel 165. Gas can be transported to the communication space 151 via the gas inlet line 17, and then transported from the communication space 151 into the receiving groove 115. For example, gas can be transported to the receiving groove 115 via the connecting channel 117. After entering the receiving groove 115, the gas will be diverted in the diversion channel 161 formed between the bottom surface 133 of the flow diversion unit 13 and the supporting surface 1151 of the receiving groove 115, such that the gas is respectively transported to the first flow diversion channel 163 between the outer side surface 135 of the flow diversion unit 13 and the radially outer side surface 1153 of the receiving groove 115, and to the second flow diversion channel 165 between the inner side surface 137 of the flow diversion unit 13 and the radially inner side surface 1155 of the receiving groove 115.

In practical applications, the gas transported to the communication space 151 via the gas inlet line 17 includes, but is not limited to, inert gas or nitrogen gas. In one embodiment of the invention, the gas inlet line 17 may be connected to a mass flow controller (MFC) 171. The gas flow rate transported to the communication space 151 via the gas inlet line 17 can be adjusted by the mass flow controller 171 in different process steps to change the gas flow rates output from the first flow diversion channel 163 and the second flow diversion channel 165. For example, the gas flow rate may be adjusted by the mass flow controller 171 according to the pressure inside the chamber 12. In addition, at least one heating unit 153 can be disposed within the base 15 to heat the wafer 14 and the gas entering the communication space 151 via the heating unit 153.

In one embodiment of the invention, the receiving groove 115 may be an annular groove, and the flow diversion unit 13 may be an annular structure. The first flow diversion channel 163 and the second flow diversion channel 165 located between the receiving groove 115 and the flow diversion unit 13 are annular grooves, wherein the circumference of the outer first flow diversion channel 163 is greater than the circumference of the inner second flow diversion channel 165.

Furthermore, the circumference of the wafer 14 placed on the carrier plate 11 is greater than the circumference of the second flow diversion channel 165 and smaller than the circumference of the first flow diversion channel 163. Therefore, when the wafer 14 is placed on the carrying surface 111 of the carrier plate 11, the second flow diversion channel 165 will be located below the wafer 14, and the first flow diversion channel 163 will be located radially outward of the wafer 14.

In practical applications, the gas output from the second flow diversion channel 165 will be transmitted to the edge region of the back-side of the wafer 14 and flow along the back-side of the wafer 14 towards the radially outer side of the carrier plate 11. In this way, the gas will form a positive pressure airflow on the back-side of the wafer 14, which can prevent the reactive gas or precursor gas from contacting the back-side of the wafer 14, thereby avoiding film formation on the back-side of the wafer 14.

The gas output from the first flow diversion channel 163 will be transmitted to the periphery of the wafer 14 and form a positive pressure airflow on the radially outer side of the wafer 14, which can prevent the reactive gas or precursor gas from flowing or diffusing to the outer side of the wafer 14, and similarly helps to avoid film formation on the back-side of the wafer 14.

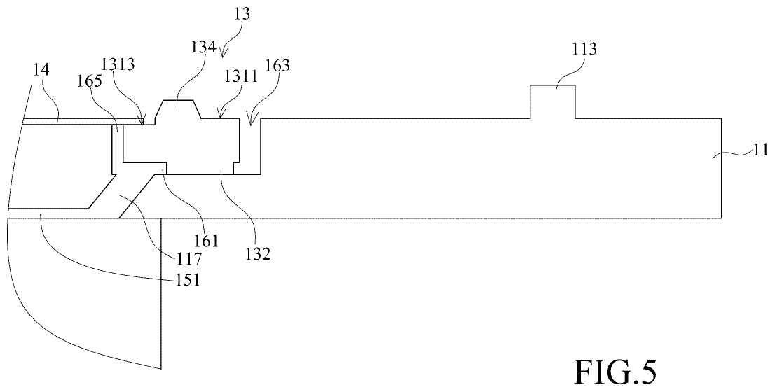

In one embodiment of the invention, as shown in FIG. 5, at least one diversion protrusion 134 may be disposed on the top surface 131 of the flow diversion unit 13, wherein the diversion protrusion 134 can divide the top surface 131 of the flow diversion unit 13 into a first region 1311 and a second region 1313. The first region 1311 is located on the outer side of the diversion protrusion 134, and the second region 1313 is located on the inner side of the diversion protrusion 134. For example, the flow diversion unit 13, the diversion protrusion 134, the first region 1311, and the second region 1313 may be annular.

When the wafer 14 is placed on the carrying surface 111 of the carrier plate 11, the wafer 14 will be located above the second region 1313 of the flow diversion unit 13 and will block part or all of the second region 1313, while the diversion protrusion 134 and the first region 1311 will be located radially outward of the wafer 14. The diversion protrusion 134 can be used to guide the gas output from the first flow diversion channel 163 and the second flow diversion channel 165 to form a gas curtain on the back-side and outer side of the wafer 14, which can be used to block the reactive gas or precursor gas and avoid film formation on the back-side of the wafer 14.

In one embodiment of the invention, the first region 1311 and the second region 1313 located on both sides of the diversion protrusion 134 may have the same or similar height. For example, the first region 1311 and the second region 1313 may be located on the same horizontal plane. The wafer 14 placed on the carrier plate 11 is located on the inner side of the diversion protrusion 134 and the first region 1311, and is located above the second region 1313. In another embodiment of the invention, the height of the first region 1311 located on the outer side of the diversion protrusion 134 may be greater than the height of the second region 1313 located on the inner side. In addition, the height of the second region 1313 may be approximately similar to the height of the carrying surface 111 of the carrier plate 11.

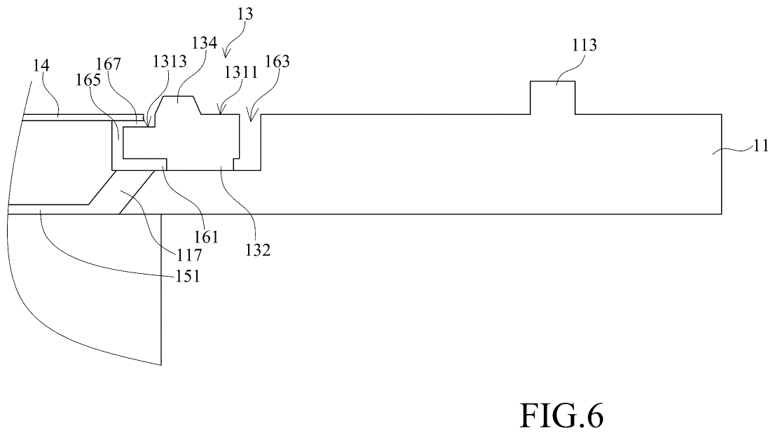

In another embodiment of the invention, as shown in FIG. 6, the height of the second region 1313 located on the inner side of the diversion protrusion 134 may be smaller than the height of the carrying surface 111 of the carrier plate 11. When the wafer 14 is placed on the carrying surface 111 of the carrier plate 11, the wafer 14 will not contact the second region 1313 of the flow diversion unit 13, and a gap 167 will be formed between the back-side of the wafer 14 and the second region 1313 of the flow diversion unit 13, wherein the second flow diversion channel 165 is connected to the gap 167. The gas output from the second flow diversion channel 165 will flow along the gap 167 between the wafer 14 and the second region 1313 of the flow diversion unit 13 and form a positive pressure in the peripheral region of the back-side of the wafer 14.

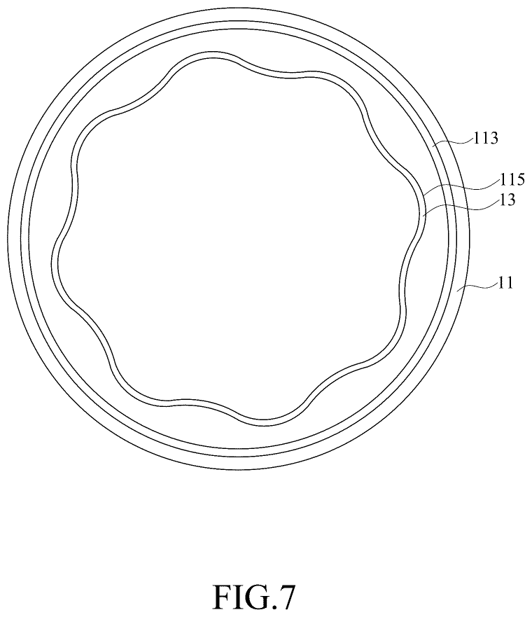

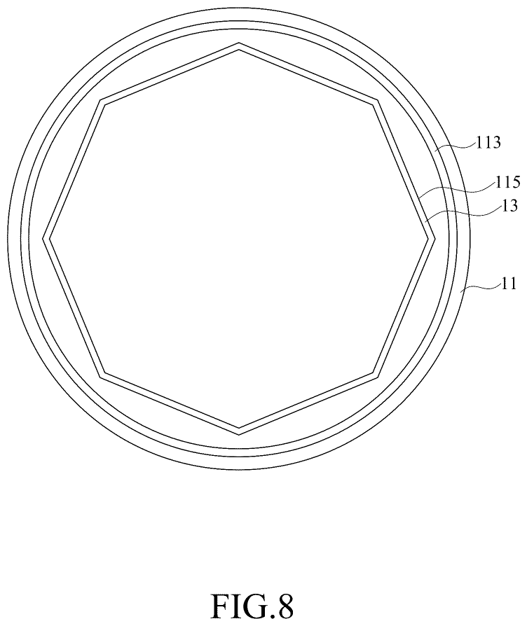

In FIG. 2, the receiving groove 115 disposed on the carrier plate 11 is an annular groove, and the flow diversion unit 13 for placement within the receiving groove 115 is annular structure or hollow cylindrical structure. In one embodiment of the invention, as shown in FIG. 7 and FIG. 8, the receiving groove 115 disposed on the carrier plate 11 is a circular wavy groove or a polygonal groove, and the flow diversion unit 13 for placement within the receiving groove 115 is a circular wavy structure or a polygonal annular structure. When the wafer 14 is placed on the carrier plate 11, a portion of the receiving groove 115 and a portion of the flow diversion unit 13 will be located below the wafer 14, while another portion of the receiving groove 115 and another portion of the diversion unit 13 will be located on the outer side of the wafer 14. For example, a portion of the outwardly protruding region of the circular wavy shape will be located on the outer side of the wafer 14, and a portion of the inwardly protruding region of the circular wavy shape will be located below the wafer 14.

This invention mainly disposes the flow diversion unit 13 on the carrier plate 11 to form the first flow diversion channel 163 and the second flow diversion channel 165 on the carrying surface 111 of the carrier plate 11. The second flow diversion channel 165 and the first flow diversion channel 163 are respectively used to guide gas to the back-side and outer side of the wafer 14, so that the reactive gas or precursor gas within the chamber 12 will not contact the back-side of the wafer 14, which can effectively prevent film formation on the back-side of the wafer 14. Through the use of the deposition equipment 10 described in this invention, it will not be necessary to grind and polish the back-side of the wafer 14 after completing the deposition step, which is beneficial for reducing process steps and costs.

The foregoing descriptions are merely preferred embodiments of this disclosure, and are not intended to limit the scope of this disclosure, that is, all equivalent changes and modifications made according to shapes, structures, features and spirits described in the scope of the claims of this disclosure shall fall within the scope of the claims of this disclosure.

What is claimed is:

1. A deposition equipment for reducing back-side deposition, comprising:
a carrier plate including a carrying surface and at least one receiving groove, wherein the carrying surface is used to carry a wafer, and the receiving groove is located on the carrying surface;
at least one flow diversion unit disposed within the receiving groove of the carrier plate, wherein the wafer located on the carrier plate overlaps with a portion of the receiving groove and a portion of the flow diversion unit, and the flow diversion unit comprising:
an outer side surface, wherein a first flow diversion channel is formed between the outer side surface of the flow diversion unit and the receiving groove;
an inner side surface, wherein a second flow diversion channel is formed between the inner side surface of the flow diversion unit and the receiving groove, and the first flow diversion channel is located on an outer side of the second flow diversion channel;
a base located below the carrier plate and used to support the carrier plate, wherein a communication space is formed between the base and the carrier plate, and the communication space connects the first flow diversion channel and the second flow diversion channel; and
a gas inlet line connected to the communication space and used to transport a gas through the communication space to the first flow diversion channel and the second flow diversion channel.

2. The deposition equipment for reducing back-side deposition as claim 1, wherein the flow diversion unit includes a bottom surface and a top surface, a plurality protruding support portions are disposed on the bottom surface, and a spacing gap is provided between adjacent protruding support portions.

3. The deposition equipment for reducing back-side deposition as claim 2, wherein the receiving groove of the carrier plate includes:
a radially outer side surface, wherein the first flow diversion channel is formed between the outer side surface of the flow diversion unit and the radially outer side surface of the receiving groove;
a radially inner side surface, wherein the second flow diversion channel is formed between the inner side surface of the flow diversion unit and the radially inner side surface of the receiving groove; and
a supporting surface, wherein the protruding support portion of the flow diversion unit is placed on the supporting surface of the receiving groove, a diversion channel is formed between the spacing gap below the bottom surface of the flow diversion unit and the supporting surface of the receiving groove, and the diversion channel connects the first flow diversion channel and the second flow diversion channel.

4. The deposition equipment for reducing back-side deposition as claim 3, wherein the flow diversion unit includes a diversion protrusion disposed on the top surface thereof, and the top surface of the flow diversion unit is divided into a first region and a second region, wherein the first region is located on an outer side of the diversion protrusion, and the second region is located on an inner side of the diversion protrusion.

5. The deposition equipment for reducing back-side deposition as claim 4, wherein the flow diversion unit, the diversion protrusion, the first region, and the second region are annular.

6. The deposition equipment for reducing back-side deposition as claim 4, wherein a height of the first region of the flow diversion unit is greater than that of the second region, and the wafer is located on the inner side of the diversion protrusion and the first region, and is located above the second region.

7. The deposition equipment for reducing back-side deposition as claim 6, wherein a gap exists between the wafer and the second region, and the gap is connected to the second flow diversion channel.

8. The deposition equipment for reducing back-side deposition as claim 1, wherein the second flow diversion channel is located below the wafer carried by the carrier plate, and the first flow diversion channel is located on an outer side of the wafer carried by the carrier plate.

9. The deposition equipment for reducing back-side deposition as claim 8, wherein the receiving groove of the carrier plate is an annular groove, a polygonal groove, or a circular wavy groove, and the flow diversion unit is an annular structure, a polygonal annular structure, or a circular wavy structure.

10. The deposition equipment for reducing back-side deposition as claim 1, wherein a cross-sectional area of the first flow diversion channel is greater than a cross-sectional area of the second flow diversion channel.
